(19) United States
(12) Patent Application Publication
(10) Pub. No.: US 2010/0042900 A1
(43) Pub. Date: Feb. 18, 2010

(54) Write Failure Handling of MLC NAND

(75) Inventors: Vadim Khmelnitsky, Foster City, CA (US); Nir Jacob Wakrat, San Jose, CA (US)

Correspondence Address: FISH & RICHARDSON P.C., PO BOX 1022, MINNEAPOLIS, MN, 55440-1022, US

(73) Assignee: APPLE INC., Cupertino, CA (US)

(21) Appl. No.: 12/193,605

(22) Filed: Aug. 18, 2008

(51) Int. Cl. G11C 29/04; G06F 11/14

(52) U.S. Cl. 714/764; 714/E11.113

(57) ABSTRACT

In a memory system, content in a defined “risk zone” of non-volatile memory is copied into volatile memory. When a write failure occurs on non-volatile memory, the risk zone is scanned sequentially to determine corrupted content. The corrupted content is restored by writing the corresponding content previously copied to volatile memory to new blocks in non-volatile memory.

### TECHNICAL FIELD

This specification is related generally to memory management.

### BACKGROUND

Multi Level Cell (MLC) technology reduces flash die size by storing 2 bits of data per physical cell. The two bits are stored by charging a floating gate of a transistor to four different voltage levels, instead of the two levels used in Single Level Cell (SLC) technology. MLC NAND flash is a flash memory technology using MLC technology to allow more bits to be stored as opposed to SLC NAND flash technologies.

An MLC memory block is typically comprised of 128 pages. When programming pages within an erasable unit, write disturb errors may be introduced, causing one or more bits to be flipped in pages other than the page that is being programmed. The time required to read and verify the contents of an entire erasable unit can cause unacceptable delays, leading programmers to defer the detection of disturb errors until the next read operation, which may occur infrequently. Consequently, these “disturbed” pages can exist for a long time before being detected. Additionally, the number of bit errors can be so numerous that the bit errors cannot be corrected by an Error Correction Code (ECC).

### SUMMARY

In a memory system, content in a defined “risk zone” of non-volatile memory is copied into volatile memory. When a write failure occurs on non-volatile memory, the risk zone is scanned sequentially to determine corrupted content. The corrupted content is restored by writing the corresponding content previously copied to volatile memory to new blocks in non-volatile memory.

The details of one or more embodiments of the subject matter described in this specification are set forth in the accompanying drawings and the description below. Other features, aspects, and advantages of the subject matter will become apparent from the description, the drawings, and the claims.

### BRIEF DESCRIPTION OF THE DRAWINGS

FIGS. 1 is a block diagram illustrating an example memory system capable of write failure handling of MLC NAND.

FIGS. 2A and 2B are flow diagrams of example processes for write failure handing of MLC NAND.

Like reference numbers and designations in the various drawings indicate like elements.

### DETAILED DESCRIPTION

### Example System

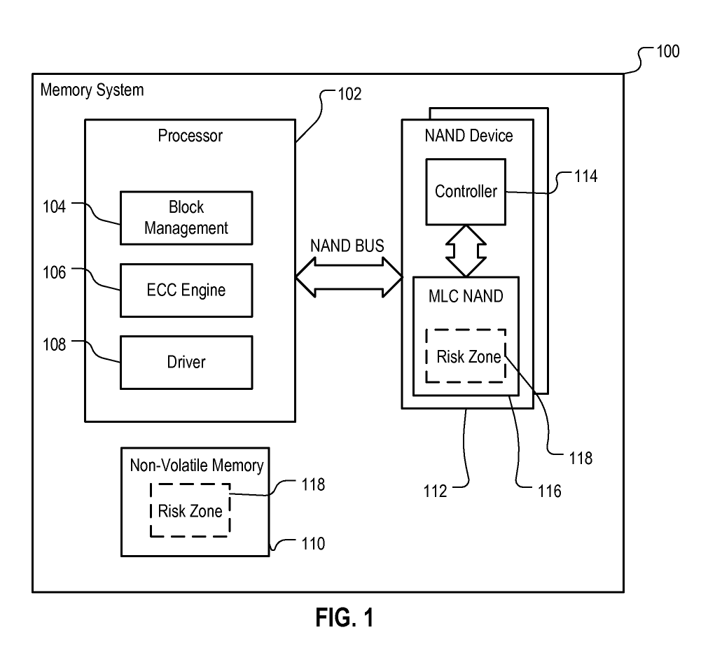

FIG. 1 is a block diagram illustrating an example memory system 100. In some implementations, the memory system 100 can be part of a portable device, such as a media player device, a personal digital assistant, a mobile phone, portable computers, digital cameras, and so on, for example. The system 100 can include a processor 102 that runs software for implementing block management 104 and an ECC engine 106. A driver 108 is included for implementing a memory interface with a memory bus (e.g., a NAND bus) coupled to one or more non-volatile memory devices 112 (e.g., MLC NAND).

The non-volatile memory devices 112 can include controllers 114 for performing read/write operations on a memory array 116. The controller 114 can also perform maintenance operations, such as wear leveling, garbage collection, etc. The memory system 100 can include volatile memory 110 which can be internal or external to the processor 102.

As previously described, when attempting to write to non-volatile memory, a write failure can corrupt one or more other pages in the same erasable unit. It is possible to determine a priori which pages are susceptible to corruption. This information is often provided by the manufacturer of the memory device 112. With this information, a “risk zone” 118 can be defined in the non-volatile memory 116 which contains one or more erasable units that are susceptible to corruption due to write disturb. For example, product information provided by a vendor (e.g., a flash manufacturer) often contains a detailed description of pages that might be affected by a write failure within a erasable unit. When a sequential write of pages is executed to a certain erasable unit, a risk zone can be established based on this information, for example, a combination of all pages that can be affected by an individual page within the write operation.

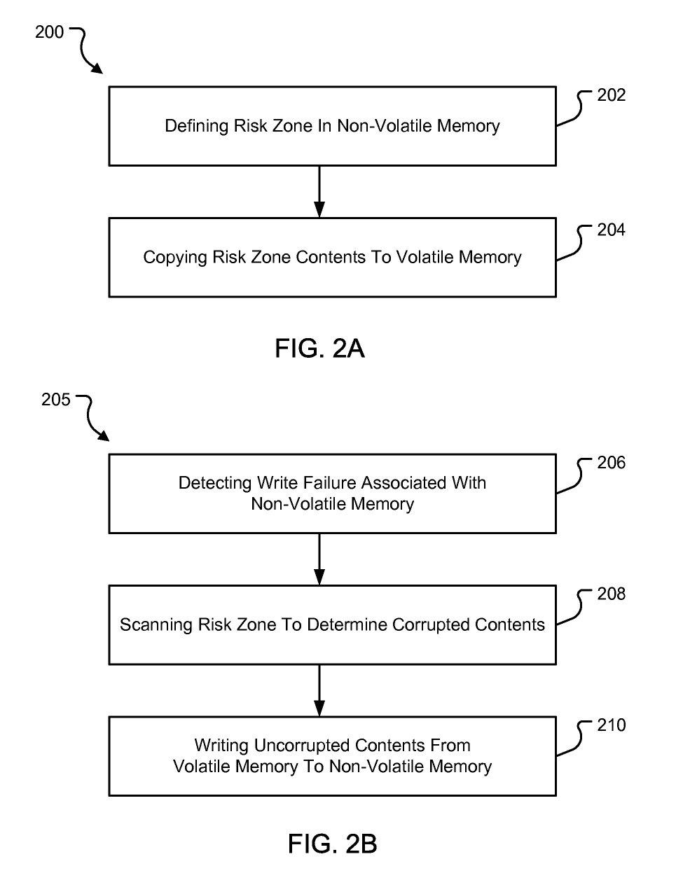

The processor 102 can initiate a copy of contents of risk zone 118 to volatile memory 110, where the contents can be persistently stored until needed during a write failure handling operation, as described in reference to FIG. 2B. In some implementations, the copy operation can be performed after the contents are first written to non-volatile memory 116 or on a scheduled basis.

If the processor 102 detects a write failure, the processor 102 can send a request to the controller 114 of the memory device 112 to scan the risk zone 118. The scanned pages can be processed by an ECC 106 engine in the processor 102 to determine if corruption has occurred due to the write failure. Since write failure corruptions are limited to one erasable unit, the processor 102 can initiate a scan of pages in a single erasable unit from the beginning and stop at the point where the corruption took place. Sequential scanning of an erasable unit is possible for file systems that write data sequentially in one block. An example of such a file system is described in U.S. patent application Ser. No. 12/193,528, for “Memory Mapping Techniques,” filed Aug. 18, 2008, which patent application is incorporated by reference herein in its entirety.

The foregoing patent application describes a file system where the “risk zone” for write disturb is potentially smaller than “risk zones” in other file systems because sequential or scattered writes are bound by one erasable unit. Thus write disturb phenomena takes place within a unit boundary.

If corrupt pages are determined, the processor 102 can initiate a write of the corresponding uncorrupted contents previously stored in volatile memory 110 to new blocks in non-volatile memory 116. Block management 104 can then reconfigure the mapping of logical sectors to the new blocks in non-volatile memory 116 (e.g., assign pointers to the new blocks) so that they can be read by the controller 114.

### Example Process

FIGS. 2A and 2B are flow diagrams of example processes 200, 205, for write failure handing of MLC NAND.

Referring to FIG. 2A, a process 200 includes defining a “risk zone” in non-volatile memory of a memory system (202) and copying the contents of the risk zone to volatile memory (204). Identification of the risk zone can be determined by reviewing manufacturer specifications for the non-volatile memory device. The copying step can be performed after the contents have been first written to the non-volatile memory or on a scheduled basis as part of a maintenance operation. The volatile memory can be located anywhere in the memory system.

Referring to FIG. 2B, a process 205 includes detecting a write failure in an erasable unit (206). The detection can be performed by a memory controller when trying to write to a memory array. An error code can be returned to a processor for implementing the process 205. If a write failure is detected, scanning can be initiated on one or more erasable units in the risk zone of the non-volatile memory to determine the location of the corrupted contents (208). In some implementations, the erasable units can be scanned sequentially to avoid scanning the entire risk zone. Sequential scanning can be performed in a memory system with a YAFFS file system, for example.

If corrupted contents are determined, the corresponding contents previously stored in volatile memory are written to new blocks in the non-volatile memory (210). Block management software executed by a processor in the memory system can reconfigure the mapping from logical sectors to the new blocks, so that the new blocks can be read by a file system. In some implementations, the file system can use the results of the scanning to perform another write to non-volatile memory of the corrupted pages or blocks rather than restoring contents from volatile memory.

A number of implementations have been described. Nevertheless, it will be understood that various modifications may be made. For example, elements of one or more implementations may be combined, deleted, modified, or supplemented to form further implementations. As yet another example, the logic flows depicted in the figures do not require the particular order shown, or sequential order, to achieve desirable results. In addition, other steps may be provided, or steps may be eliminated, from the described flows, and other components may be added to, or removed from, the described systems. Accordingly, other implementations are within the scope of the following claims.

What is claimed is:

1. A method comprising:
defining a risk zone in non-volatile memory of a memory system;
copying contents of the risk zone into volatile memory of the memory system;
detecting a write failure on the non-volatile memory;
scanning the risk zone to determine corrupted pages; and
replacing contents of corrupted pages with corresponding contents stored in the volatile memory.

2. The method of claim 1, where the non-volatile memory is Multi Level Cell (MLC) NAND.

3. The method of claim 1, where the scanning is performed sequentially on an erasable unit of non-volatile memory.

4. The method of claim 1, where determining corrupted pages is performed using an error correcting code engine.

5. A memory system comprising:
non-volatile memory including a defined risk zone that is susceptible to write disturb errors;
volatile memory storing contents of at least a portion of the risk zone; and
a processor coupled to the non-volatile memory and the volatile memory, the processor operable for detecting a write failure, scanning the risk zone in the non-volatile memory for corrupted contents due to the write failure, and responsive to determining corrupted contents, copying corresponding uncorrupted contents from the volatile memory to the non-volatile memory.

6. The system of claim 5, where the non-volatile memory is Multi Level Cell (MLC) NAND.

7. A computer-readable medium having instructions stored thereon, which, when executed by a processor, causes the processor to perform operations comprising:
defining a risk zone in non-volatile memory of a memory system;
copying contents of the risk zone into volatile memory of the memory system;
detecting a write failure on the non-volatile memory;
scanning the risk zone to determine corrupted pages; and
replacing contents of determined corrupted pages with corresponding contents stored in the volatile memory.

8. The computer-readable medium of claim 7, where the non-volatile memory is Multi Level Cell (MLC) NAND.

9. The computer-readable medium of claim 7, where the scanning is performed sequentially on an erasable unit of non-volatile memory.

10. The computer-readable medium of claim 7, where determining corrupted pages is performed using an error correcting code engine.

11. A memory system comprising:
means for defining a risk zone in non-volatile memory of a memory system;
means for copying contents of the risk zone into volatile memory of the memory system;
means for detecting a write failure on the non-volatile memory;
means for scanning the risk zone to determine corrupted pages; and
means for replacing contents of determined corrupted pages with corresponding contents stored in the volatile memory.
